(19) United States
(12) Patent Application Publication
(10) Pub. No.: US 2024/0380107 A1
(43) Pub. Date: Nov. 14, 2024

(54) HEAT-DISSIPATING MAGNETIC FIELD SHIELDING SHEET AND ANTENNA MODULE AND ELECTRONIC DEVICE INCLUDING SAME

(71) Applicant: AMOSENSE CO.,LTD, Cheonan-si, Chungcheongnam-do (KR)

(72) Inventor: Kil Jae JANG, Cheonan-si, Chungcheongnam-do (KR)

(73) Assignee: AMOSENSE CO.,LTD, Cheonan-si, Chungcheongnam-do (KR)

(21) Appl. No.: 18/686,752

(22) PCT Filed: Aug. 26, 2022
(86) PCT No.: PCT/KR2022/012814

§ 371 Date: Jun. 14, 2024

(30) Foreign Application Priority Data
Aug. 27, 2021 (KR) 10-2021-0113797

(51) Int. Cl. H01Q 1/52; B32B 7/12; B32B 15/01; H01Q 1/02

(52) U.S. Cl. CPC H01Q 1/526; B32B 7/12; B32B 15/011; H01Q 1/02; B32B 2307/208; B32B 2307/302; B32B 2307/7376; B32B 2457/00

(57) ABSTRACT

A magnetic field shielding sheet including: a plurality of magnetic layers having at least one eddy current reduction pattern part formed thereon; and a heat-dissipating magnetic field shielding unit including heat-dissipating adhesive members arranged between adjacent magnetic layers to improve the heat transfer in the thickness direction of the magnetic field shielding unit. By the magnetic field shielding sheet, the occurrence of eddy currents can be reduced, a high magnetic permeability of 2000 or more can be implemented while having a very thin thickness, and eddy currents that increase by selectively forming an eddy current reduction pattern locally in a region corresponding to the antenna among the entire area and the heat generated by the increase in eddy currents due to the thinner thickness according to the recent trend of being light, thin, short and miniaturized and the resulting decrease in resistance can be quickly discharged to the outside.

### CROSS REFERENCE TO RELATED APPLICATION

This application is a 35 U.S.C. § 371 National Stage of International Patent Application No. PCT/KR2022/012814, filed Aug. 26, 2022, claiming benefit from Korean Patent Application No. 10-2021-0113797, filed Aug. 27, 2021, the disclosures of which are incorporated herein in their entirety by reference, and priority is claimed to each of the foregoing.

### TECHNICAL FIELD

The present invention relates to a heat-dissipating magnetic field shielding sheet, and more particularly, to a heat-dissipating magnetic field shielding sheet, and an antenna module and an electronic device including the same.

### BACKGROUND

Various functions that have been widely installed in electronic devices recently, such as near field communication (NFC), wireless power transmission (WPT), and magnetic secure transmission (MST), are performed using a non-contact transmission method. This non-contact transmission method is implemented through an antenna that transmits or receives a magnetic field, and a magnetic field shielding sheet arranged on one side of the antenna to smoothly transmit or receive the magnetic field.

Typically, sheets with magnetic properties such as soft magnetic alloy ribbon sheets, ferrite sheets, or polymer sheets with magnetic powder dispersed therein have been used as magnetic field shielding sheets.

Among these magnetic field shielding sheets, in the case of soft magnetic alloy ribbon sheets, a sheet in which the ribbon sheet is split into multiple pieces is used to significantly reduce loss due to eddy current or improve the flexibility of the sheet itself.

However, there is a problem of increasing the production cost as a separate flake process is required to split the soft magnetic alloy ribbon sheet into multiple pieces.

In addition, it was required to repeat the flake process several times because the size of the split piece was too large and the size of the split piece varied depending on the location when performing the flake process in a sheet state equipped with a soft magnetic alloy ribbon sheet. However, performing multiple flake processes has a problem of significantly reducing magnetic permeability by increasing the proportion of pieces that are excessively small in size.

However, if the number of flake processes is reduced to prevent a decrease in magnetic permeability, there is a risk of producing sheets with large losses due to eddy currents and non-uniform magnetic properties. In addition, Joule heat generated by eddy currents reduces the transmission and reception efficiency of signals transmitted in a non-contact manner through antennas and degrades the performance of surrounding electronic components, making it difficult to achieve the original purpose of reducing magnetic loss and heat generation caused by eddy currents through the flake process.

Accordingly, it is urgent to develop a heat-dissipating magnetic field shielding sheet that has high magnetic permeability without increasing the overall thickness of the magnetic field shielding sheet and can quickly discharge Joule heat from the eddy currents that may occur to the outside.

### SUMMARY OF THE INVENTION

The present invention has been devised to solve the above problems, and is directed to providing a heat-dissipating magnetic field shielding sheet, and an antenna module and an electronic device including the same that can block the magnetic field effect on the user's human body and improve the magnetic characteristics to improve the radio signal transmission/reception efficiency and transmission distance, while minimizing or preventing a decrease in radio signal transmission/reception efficiency and performance degradation of peripheral components due to heat that may be caused by improved magnetic characteristics.

In order to solve the above problems, the present invention provides a heat-dissipating magnetic field shielding sheet, including a heat-dissipating magnetic field shielding unit, having: a plurality of magnetic layers having at least one eddy current reduction pattern part formed thereon, and a heat-dissipating adhesive member disposed between adjacent magnetic layers to improve heat transfer in the thickness direction of a magnetic field shielding unit.

According to an exemplary embodiment of the present invention, the magnetic field shielding sheet is a magnetic field shielding sheet arranged on one surface of an antenna, the antenna including a hollow portion having a predetermined area in the center and a pattern part surrounding the hollow portion, and the eddy current reduction pattern part may be provided at a position corresponding to a region in which the pattern part is disposed.

In addition, the magnetic layer may be a soft magnetic alloy ribbon sheet including transition metals.

In addition, the ribbon sheet may be a sheet containing amorphous or nanocrystalline grains.

In addition, the eddy current reduction pattern part may be a crack part in which a magnetic material constituting a magnetic layer in a predetermined region is divided into a plurality of pieces, or may be a penetration part penetrating the predetermined region.

In addition, the heat-dissipating magnetic field shielding sheet is attached to a first antenna and a second antenna, and the eddy current reduction pattern part may include a first eddy current reduction pattern part formed to intersect both the first antenna and the second antenna, and a second eddy current reduction pattern part formed to intersect the second antenna.

In addition, a plurality of first eddy current reduction pattern parts may be arranged radially around a central portion of the first antenna, and the second eddy current reduction pattern part may be formed between at least one pair of the first eddy current reduction pattern parts disposed adjacent to each other to intersect the pattern of the second antenna.

In addition, the first eddy current reduction pattern part and the second eddy current reduction pattern part may be formed linearly with a predetermined width and length, and the length of the second eddy current reduction pattern part may be smaller than the length of the first eddy current reduction pattern part.

In addition, the second antenna may include a first pattern disposed outside the first antenna and a first connection pattern connected to the first pattern, and the eddy current reduction pattern part may be arranged so as not to overlap the first connection pattern.

In addition, the second antenna may include a second pattern disposed inside the first antenna and a second connection pattern connected to the second pattern, and the eddy current reduction pattern part may be arranged so as not to overlap the second connection pattern.

In addition, the heat-dissipating adhesive member may be made of a heat-dissipating adhesive layer in which a heat dissipation filler in a binder matrix is dispersed, or may be a heat dissipating double-sided tape having the heat-dissipating adhesive layer on both surfaces of a base material.

In addition, the heat dissipation filler may include one or more of a carbon-based filler, a metal filler, and a ceramic filler.

In addition, the thickness of the magnetic layer may be 15 to 35 μm, and the thickness of the heat-dissipating adhesive member may be 3 to 50/m.

In addition, the heat-dissipating magnetic field shielding sheet may further include a protection part having a protective film disposed on one surface of the heat-dissipating magnetic field shielding unit; and an attachment part disposed on the other surface of the heat-dissipating magnetic field shielding unit opposite to the one surface, and for fixing a magnetic field shielding sheet to an attachment target surface.

In addition, the present invention provides an antenna module, including an antenna unit having an antenna including a hollow portion having a predetermined area and a pattern part surrounding the hollow portion in the central portion; and a heat-dissipating magnetic field shielding sheet according to the present invention disposed on one surface of the antenna unit. According to an exemplary embodiment of the present invention, the antenna may include one or more of an antenna for wireless power transmission (WPT), an antenna for magnetic secure transmission (MST), and an antenna for near field communication (NFC).

In addition, the present invention provides an electronic device including an antenna module according to the present invention.

### Advantageous Effects

The heat-dissipating magnetic field shielding sheet according to the present invention can increase the overall resistance through the eddy current reduction pattern part to reduce the occurrence of eddy currents, and implement high magnetic permeability of 2000 or more while having a very thin thickness. In addition, the present invention can quickly discharge eddy currents that increase by selectively forming an eddy current reduction pattern locally in a region corresponding to the antenna among the entire area, and a heat generated by the increase in eddy currents due to the thinner thickness according to the recent trend of being light, thin, short and miniaturized and the resulting decrease in resistance, thereby minimizing performance degradation of peripheral components such as antennas, and so it can be widely applied to various electronic devices, including portable electronic devices.

### BRIEF DESCRIPTION OF THE DRAWINGS

FIG. 1 is a perspective view of a heat-dissipating magnetic field shielding sheet according to an exemplary embodiment of the present invention.

FIG. 2 is a cross-sectional view and a partial enlarged view of FIG. 1.

FIG. 3 is an enlarged cross-sectional view of a heat-dissipating magnetic field shielding unit included in an exemplary embodiment of the present invention.

FIG. 4 is an enlarged view of an eddy current reduction pattern part according to an exemplary embodiment of the present invention.

FIG. 5 is an enlarged cross-sectional view taken along the boundary line X-X′ in FIG. 4.

FIGS. 6 to 9 are a plan view and a partial enlarged view of a heat-dissipating magnetic field shielding sheet according to various embodiments of the present invention.

FIG. 10 is an exploded perspective view of an antenna module according to an exemplary embodiment of the present invention.

FIGS. 11 to 13 are plan views of an antenna module according to various embodiments of the present invention.

### DETAILED DESCRIPTION OF THE EMBODIMENTS

Hereinafter, exemplary embodiments of the present invention will be described in detail so that those of ordinary skill in the art can readily implement the present invention with reference to the accompanying drawings. The present invention may be embodied in many different forms and is not limited to the embodiments set forth herein. In the drawings, parts unrelated to the description are omitted for clarity of description of the present invention, and same or similar reference numerals denote same elements.

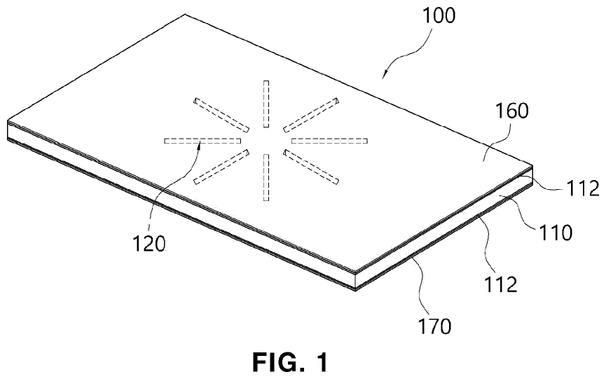

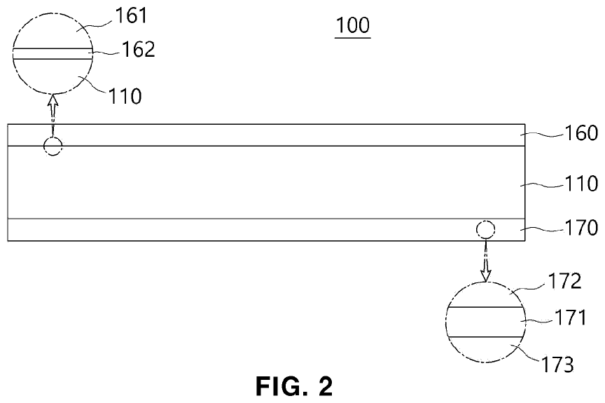

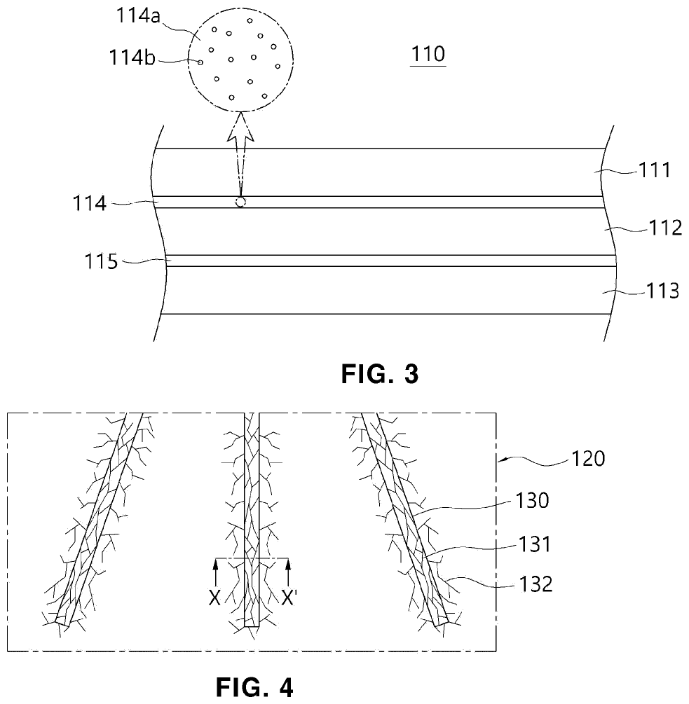

Describing with reference to FIGS. 1 to 4, the heat-dissipating magnetic field shielding sheet 100 according to an exemplary embodiment of the present invention includes a heat-dissipating magnetic field shielding unit 110, and may further include a protection part 160 provided on one surface of the heat-dissipating magnetic field shielding unit 110 and an attachment part 170 provided on the other surface of the heat dissipation magnetic field shielding unit 110 facing the one surface.

The heat-dissipating magnetic field shielding unit 110 includes a plurality of magnetic layers 111, 112, 113 having at least one eddy current reduction pattern part 120 formed thereon; and heat-dissipating adhesive members 114, 115 disposed between adjacent magnetic layers 111, 112, 113 to fix the magnetic layers 111, 112, 113 and function to improve heat transfer by rapidly dissipating heat generated from the magnetic layers 111, 112, 113 in the thickness direction of the magnetic field shielding unit 110.

The plurality of magnetic layers 111, 112, 113 may be made of a known magnetic material capable of shielding a magnetic field generated and transmitted from an antenna or received from the outside. For example, the magnetic layers 111, 112, 113 may be soft magnetic alloy ribbon sheets, and specifically, may be soft magnetic alloy ribbon sheets containing transition metals such as iron, nickel, and cobalt, and as a more specific example, may include one or more of Fe—Si—B, Fe—Si—B—Cu, Fe—Si—B—C, Fe—Si—B—C—Cu Fe—B—Cu, Fe—B—C—Cu, Fe—B—C—Cu—Nb, and alloys in which some or all of Fe is replaced with Ni or Co. In addition, in the case of the soft magnetic alloy ribbon sheet above, it may be a soft magnetic alloy containing amorphous or nanocrystalline grains.

In addition, the magnetic layers 111, 112, 113 may be stacked in the thickness direction, and for example, two or three magnetic layers may be provided, but are not limited thereto and may be appropriately changed in consideration of desired magnetic properties, design conditions, and the like.

In addition, each of the multiple magnetic layers 111, 112, 113 may have a thickness of 15 to 35 μm, and if the thickness of each magnetic layer exceeds 35 μm, it is difficult to implement a thinned magnetic field shielding sheet, and the flexibility of the magnetic field shielding sheet may decrease. Furthermore, if the thickness is less than 15 μm, handling will deteriorate, and there is a high risk of damage or additional cracks in the magnetic layer due to the manufacturing process of the magnetic field shielding sheet, the process of attaching it to parts such as antennas, or the external force applied during use, and because of this, there is a risk that the initially set magnetic properties may change.

Next, at least one eddy current reduction pattern part 120 is formed on the magnetic layer 111, 112, 113, thereby increasing the overall resistance of the heat-dissipating magnetic field shielding unit 110 to minimize loss or heat generation due to eddy currents or impact on the antenna due to eddy currents.

The eddy current reduction pattern part 120 may have any configuration capable of increasing the overall resistance of the heat-dissipating magnetic field shielding unit 110. In addition, the eddy current reduction pattern part 120 may be formed to occupy any one region of the inner regions of the heat-dissipating magnetic field shielding unit 110. In addition, the shape of the eddy current reduction pattern part 120 occupying the above one region is not limited, and may be, for example, a slit shape with a predetermined length and width, but is not limited thereto, and may be formed to occupy a predetermined area in a shape such as ‘+’, ‘x’, ‘*’, ‘⊥’ or ‘·’.

In addition, the number of eddy current reduction pattern parts 120 may be one or more, and the size may be 0.1 to 0.4 mm in width when it is slit-shaped, but it may be provided in an appropriate number and size in consideration of the structure, shape, desired eddy current reduction level, antenna size, and the like. In addition, the eddy current reduction pattern part 120 may be partially formed in a partial region of the entire regions of the heat-dissipating magnetic field shielding unit 110.

In addition, if the article placed in one surface of the heat-dissipating magnetic field shielding sheet 100 is an antenna, the eddy current reduction pattern part 120 may be placed on some of the regions corresponding to the antenna, and may be placed in various locations in consideration of the shape and position of the antenna. For example, in the case of an antenna including a hollow portion having a predetermined area and a pattern part surrounding the hollow portion in the central portion, it may be formed at a position corresponding to a region in which the pattern part is placed.

In addition, the eddy current reduction pattern part 120 may be, for example, composed of a crack part 130 in which a magnetic material constituting the magnetic layers 111, 112, 113 in a predetermined region inside the heat-dissipating magnetic field shielding unit 110 is divided into a plurality of pieces, or a penetration part 140 penetrating the predetermined region.

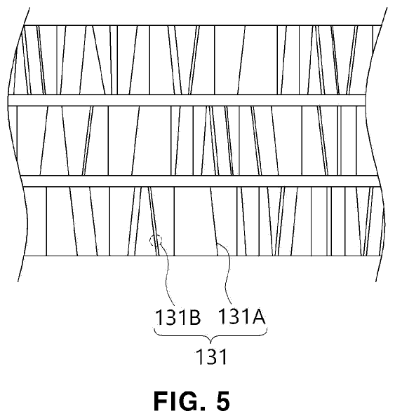

First, the crack part 130 among various forms of the eddy current reduction pattern part 120 will be described. As shown in FIGS. 4 and 5, the crack part 130 is formed by splitting a magnetic material existing in a predetermined region into a plurality of pieces, and may include a crack 131. In this case, the remaining part of the entire region of the heat-dissipating magnetic field shielding unit 110 except for the crack part 130 may not be separated into a plurality of pieces.

Here, the crack 131 included in the crack part 130 may be formed by splitting a magnetic layers 111, 112, 113 by applying an external force to the laminate in which the plurality of magnetic layers 111, 112, 113 are stacked through a pressing member or the like. In this case, a plurality of pieces separated by the crack 131 may be disconnected from each other, but may maintain a state 131A in contact with each other, or a fine space 131B may be formed between adjacent pieces separated. Meanwhile, the fine space 131B may be distinguished from the penetration part 140 in that it has a very fine width compared to the penetration part 140 to be described later, and is formed in any one magnetic layer 111, 112, 113.

Meanwhile, cracks 131 are not formed only within a border dividing the predetermined region described above in the heat-dissipating magnetic field shielding unit 110, but additionally, a plurality of microcracks 132 may be formed to extend outside the predetermined region border defining the eddy current reduction pattern part 120. That is, when pressed through a pressing member to form the crack part 130 in the heat-dissipating magnetic field shielding unit 110, microcracks 132 extending outside the region extending from the predetermined region in addition to the desired region may be formed together.

Meanwhile, as another example of the crack part 130 including the crack 131, the crack part 130 may include a plurality of regular cracks formed in a predetermined shape and a plurality of irregular cracks derived from the plurality of regular cracks.

As described above, the crack part 130 including the crack 131 may increase resistance as the magnetic material is separated into a plurality of pieces, thereby reducing an eddy current.

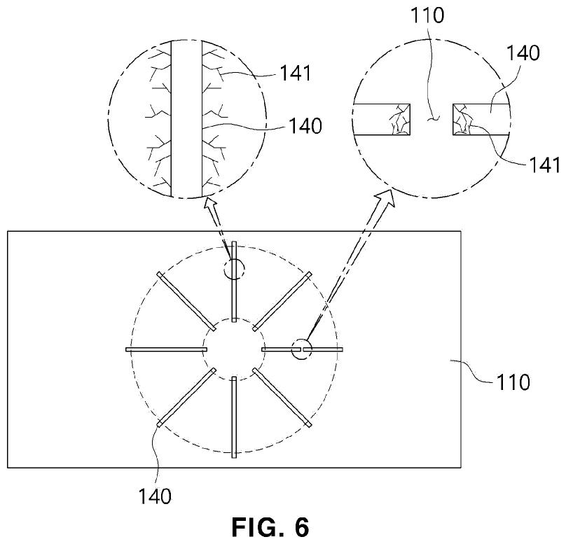

Next, the penetration part (140), another example of the eddy current reduction pattern part 120, is formed to penetrate two surfaces facing the thickness direction of the heat-dissipating magnetic field shielding unit 110, as shown in FIG. 6. In this case, a plurality of microcracks 141 formed to extend outward from the border of the region occupying the penetration part 140 due to external force applied in the process of forming the penetration part 140 may be further included, and the microcracks 141 may help reduce eddy currents together with the penetration part 140.

In this case, the plurality of microcracks 141 formed from the penetration part 140 may or may not be connected to each other. In addition, only some of the plurality of microcracks 141 may be connected to each other. Accordingly, the heat-dissipating magnetic field shielding sheet 100 according to an exemplary embodiment of the present invention may increase overall resistance through the penetration part 140 and the plurality of microcracks 141 formed in the heat-dissipating magnetic field shielding unit 110, thereby reducing eddy currents.

As a non-limiting example of the penetration part 140, as shown in FIG. 6, the penetration part 140 may be formed in a slit shape having a length longer than a width.

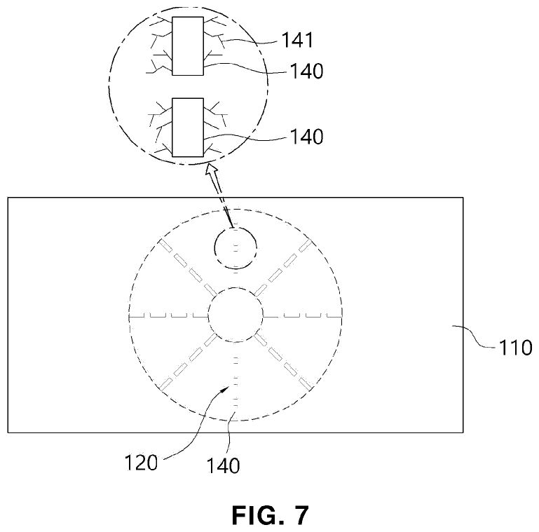

As another example, as shown in FIG. 7, in the case of the penetration part 140, a plurality of penetration parts 140 may be linearly arranged in one direction at a predetermined interval therebetween so that the plurality of penetration parts 140 form a dotted line shape as a whole.

Meanwhile, if two or more antennas with different uses are provided, antenna performance may deteriorate due to the introduction of the eddy current reduction pattern part 120 described above. To prevent this, in an embodiment of the present invention, the eddy current reduction pattern part 120 may include a first eddy current reduction pattern part 121 and a second eddy current reduction pattern part 122.

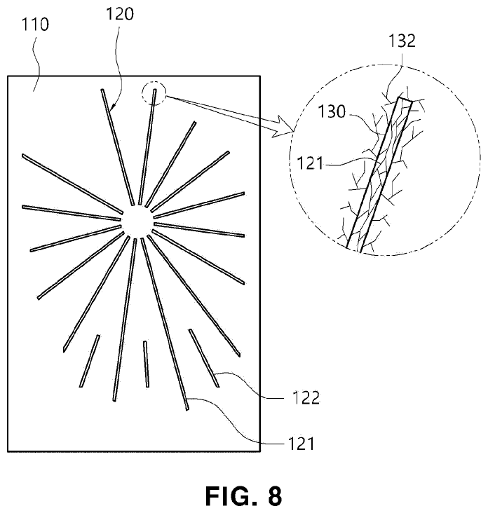

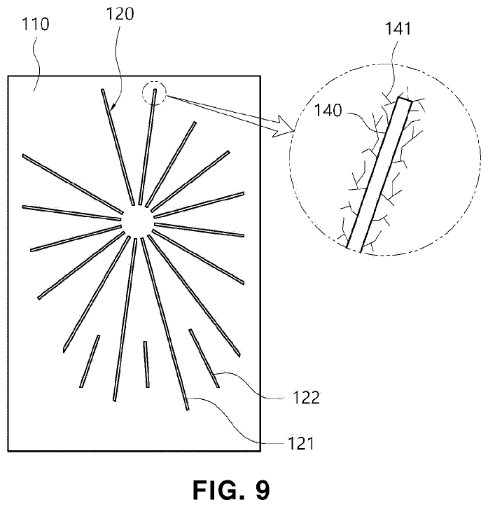

First, the first eddy current reduction pattern part 121 may an eddy current reduction pattern part 120 formed to intersect both a first antenna 220 and a second antenna 230 constituting an antenna unit 200, 200′. In this case, as shown in FIGS. 8 and 9, the first eddy current reduction pattern part 121 may be formed to extend to have a relatively long length compared to the second eddy current reduction pattern part 122 to be described later, so that it may be arranged to intersect both the first antenna 220 and the second antenna 230. Through this, the magnetic field shielding sheet 100 according to an exemplary embodiment of the present invention can reduce the influence of eddy currents on the plurality of antennas 220 and 230 with only the first eddy current reduction pattern part 121, which has a predetermined area and is formed in a single shape.

Next, the second eddy current reduction pattern part 122 may be formed to intersect only one antenna of the first antenna 220 and the second antenna 230. In this case, as shown in FIGS. 8 and 9, the second eddy current reduction pattern part 122 can reduce the influence of eddy currents on a local region that is difficult to cover with only the first eddy current reduction pattern part 121, which covers a wide region.

Meanwhile, Korean patent application numbers 10-2020-0073631, 10-2021-0022412 and 10-2021-0050568 by the applicant of the present invention are inserted by reference in their entirety to the present invention in relation to the magnetic field shielding unit 110 including a plurality of magnetic layers having at least one eddy current reduction pattern part 120.

Next, the heat-dissipating adhesive members 114, 115 disposed between the plurality of magnetic layers 111, 112, 113 described above will be described.

The heat-dissipating adhesive members 114, 115 are arranged between adjacent magnetic layers 111, 112, 113 to fix the magnetic layers 111, 112, 113, and function to improve heat transfer by rapidly dissipating heat generated from the magnetic layers 111, 112, and 113 in the thickness direction of the magnetic field shielding unit 110. In other words, in the past, the entire regions of the magnetic layer were split into multiple pieces and formed separately to reduce eddy currents, and since the eddy current reduction pattern part 120 described above is formed only in a certain region, it is difficult to avoid a heat generation problem caused by eddy current. However, the heat-dissipating adhesive members 114 and 115 described above may be advantageous to prevent performance degradation of surrounding electronic components such as antennas by quickly transferring heat that may be generated by the eddy current reduction pattern part 120 formed only in a certain region to other heat dissipation members such as heat sinks.

The heat-dissipating adhesive members 114, 115 are not limited in the case of members designed to have a predetermined adhesive performance and heat dissipation performance at the same time, and may be, for example, made of a heat-dissipating adhesive layer in which a heat dissipation filler 114b in a binder matrix 114a is dispersed, or may be a heat dissipating double-sided tape having the heat-dissipating adhesive layer on both surfaces of the base material.

The binder matrix 114a may be formed of a known binder resin having adhesive performance. Specifically, the binder resin may be a mixture of one or two or more types of alkyd resin, epoxy resin, urethane resin, vinyl chloride resin, acrylic resin, silicone resin, fluorine resin, polyester resin, phenol resin, melamine resin, and the like. In addition, the binder matrix 114a may further include a known curing agent and curing accelerator for curing these binder resins.

In addition, the heat dissipation filler 114b may include a known filler having heat dissipation performance without limitation, and for example, may include one or more of a carbon-based filler, a metal filler, and a ceramic filler. For example, the carbon-based filler may include one or more of carbon black, graphite, graphene, acetyl black, carbon nanotube, fullerene, carbon fiber, or the like. In addition, the metal filler may be aluminum, copper, silver, platinum, gold, nickel, stainless steel, magnesium, iron, or an alloy or mixture of two or more of these. In addition, the ceramic filler may include one or more of magnesium oxide, titanium dioxide, aluminum nitride, silicon nitride, boron nitride, aluminum oxide, silica, zinc oxide, silicon carbide, barium titanate, strontium titanate, beryllium oxide, manganese oxide, or the like.

The particle diameter of the heat dissipation filler 114b may be 10 nm to 10 μm, but is not limited thereto, and may be appropriately changed considering the thickness of the heat-dissipating adhesive layer. In addition, the content of the heat dissipation filler 114b may be contained in an amount of 10 to 300 parts by weight based on 100 parts by weight of the binder matrix 114a. In addition, the shape of the heat dissipation filler 114b may be generally spherical, but is not limited thereto, and may be a plate shape, a fiber shape, a rod shape, or an atypical shape.

Meanwhile, the thickness of the heat-dissipating adhesive member 114, 115 may be 3 to 50 μm. In addition, when it is in the form of a heat dissipating double-sided tape including a base material, the base material may be a known film, for example, a PET film, and the thickness may be 5 to 30 μm.

A protection part 160 for protecting the exposed magnetic layer 111 may be further provided on one side of the heat-dissipating magnetic field shielding unit 110 described above. As the protection part 160, a known protection member may be used without limitation, and for example, the protection part may be formed by forming a first adhesive layer 162 on one surface of a protective film 161, and the protective film 161 may be fixed to one surface of the heat-dissipating magnetic field shielding unit 110 via the first adhesive layer 162. The protective film 161 may be a known polymer film, and examples thereof may include polyethylene, polypropylene, polyimide, crosslinked polypropylene, nylon, polyurethane-based resin, acetate, polybenzimidazole, polyimide amide, polyetherimide, polyphenylene sulfide (PPS), polyethylene terephthalate (PET), polytrimethylene terephthalate (PTT), polybutylene terephthalate (PBT), polyvinylidene fluoride (PVDF), polytetrafluoroethylene (PTFE), polychlorotrifluoroethylene (PCTFE), polyethylene tetrafluoroethylene (ETFE), and the like, which may be used alone or in combination. In addition, the protective film 161 may have a thickness of 1 to 100 μm, preferably 10 to 30 μm, but is not limited thereto.

In addition, the first adhesive layer 162 may be a layer formed of a known adhesive, and its material may be a mixture of one or two or more types of alkyd resin, epoxy resin, urethane resin, vinyl chloride resin, acrylic resin, silicone resin, fluorine resin, polyester resin, phenol resin, melamine resin, and the like. Meanwhile, in order to achieve improved heat dissipation performance, the first adhesive layer 162 may also further include a heat dissipation filler. In addition, the first adhesive layer 140b may have a thickness of 3 to 30 μm, but is not limited thereto, and may be practiced by changing it according to the purpose.

Meanwhile, when the eddy current reduction pattern part 120 provided in the heat-dissipating magnetic field shielding unit 110 is the penetration part 140, the protection part 160 may also include a penetration part at a position corresponding to the penetration part 140.

In addition, the heat-dissipating magnetic field shielding unit may further include an attachment part 170 on an opposite surface facing the surface on which the protection part 160 is formed. The attachment part 170 is for fixing the heat-dissipating magnetic field shielding sheet 100 to an attachment target surface, and may include a known adhesive layer or bonding layer. For example, the attachment part 170 may include a second adhesive layer 172 and a third adhesive layer 173 formed on both surfaces of a base film 171, respectively, or may be formed only of an adhesive layer by omitting the base film 171. Here, since the material of the second adhesive layer 172 and the third adhesive layer 173 may be a known adhesive, detailed description thereof herein will be omitted. In addition, the third adhesive layer 173 may be composed of an adhesive layer to improve reworkability on an attachment target surface, and the adhesive layer may be formed of a known adhesive component such as acrylic. In addition, since the material of the base film 171 is the same as the description of the material of the protective film described above, detailed description will be omitted. In addition, the thickness of the second adhesive layer 172 and the third adhesive layer 173 may each independently be 5 to 50 μm. In addition, the thickness of the base film 171 may be 10 to 100 μm.

The heat-dissipating magnetic field shielding sheet 100 according to an exemplary embodiment of the present invention described above may have a high magnetic permeability of 2000 or more in a very thin thickness while minimizing an influence due to an eddy current by partially forming an eddy current reduction pattern part 120 in a partial region corresponding to a region in which an antenna is arranged to increase the overall resistance of the sheet itself. For example, the magnetic field shielding sheet 100 according to an exemplary embodiment of the present invention may have a high magnetic permeability of 2000 or more even in a very thin thickness with an overall thickness of 55 μm to 85 μm.

Because of this, the magnetic field shielding sheet 100 according to an exemplary embodiment of the present invention can increase the inductance of at least one antenna while realizing thinning through a very thin thickness.

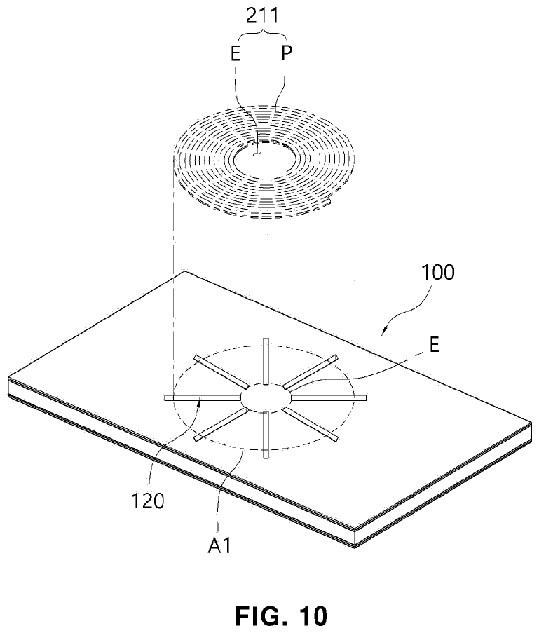

As shown in FIG. 10, in the case of such an eddy current reduction pattern part 120, the eddy current reduction pattern part 120 may be formed only on a partial area corresponding to the pattern part of the antenna 211 based on the central point of the internal hollow portion E of the antenna 211, and a partial area in which the pattern part P of the antenna 211 is arranged may be, for example, an arrangement region A1 shown in FIG. 10.

In addition, the eddy current reduction pattern part 120 formed over a partial area corresponding to the pattern part P of the antenna 211 may be formed radially, for example. However, the form of arrangement of the eddy current reduction pattern part 120 in the magnetic field shielding sheet 100 according to an exemplary embodiment of the present invention is not limited thereto, and as long as it is formed at a position corresponding to the antenna 211, the eddy current reduction pattern part 120 may be formed in various ways.

The above-described heat-dissipating magnetic field shielding sheet 100 according to an exemplary embodiment of the present invention may be implemented as an antenna module together with an antenna unit including an antenna performing a predetermined function.

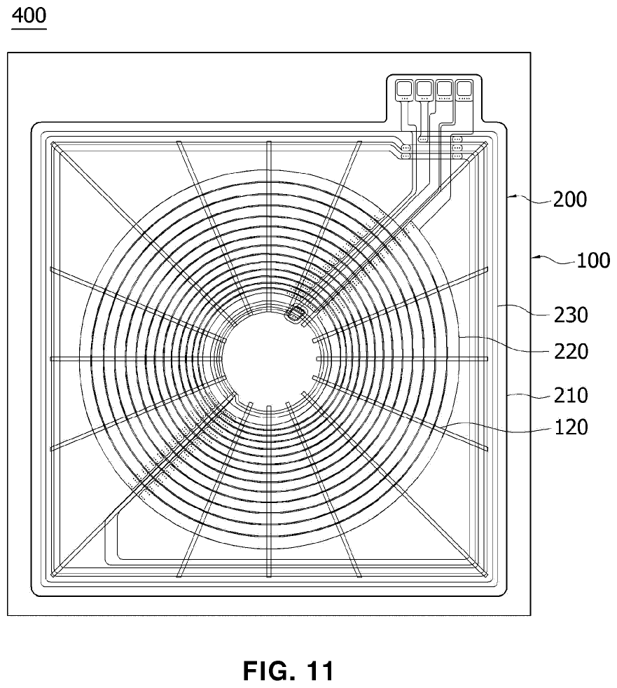

For example, as shown in FIG. 11, an antenna module 400 may include an antenna unit 200 including a first antenna 220, and a heat-dissipating magnetic field shielding sheet 100, arranged on one surface of the antenna unit 200, that shields the magnetic field, focuses the magnetic field in the direction of the need, and transfers the Joule heat generated by the eddy current to the outside.

Here, the antenna unit 200 may be a combo antenna unit including a second antenna 230 disposed to surround the outer periphery of the first antenna 220 in addition to a first antenna 220, and the first antenna 220 and the second antenna 230 may be antenna patterns patterned on one surface of a circuit board 210. Here, the first antenna 220 may be, for example, an antenna for wireless power transmission (WPT), the second antenna 230 may be an antenna for wireless communication, for example, an NFC antenna.

In this way, if the antenna unit 200 is formed as a combo antenna unit, the eddy current reduction pattern part 120 may be formed only in a region corresponding to a region in which the first antenna 220 and the second antenna 230 are disposed of among the entire region of the heat-dissipating magnetic field shielding unit 110, or may be formed only in a region corresponding to a region in which the first antenna 220 is disposed, unlike the one shown in FIG. 11. That is, the eddy current reduction pattern part 120 may not be formed in the remaining region of the combo antenna unit 200 except for a region corresponding to a region in which the first antenna 220 is disposed. In particular, the eddy current reduction pattern part 120 may not be formed in a region corresponding to a region in which the second antenna 230 is disposed.

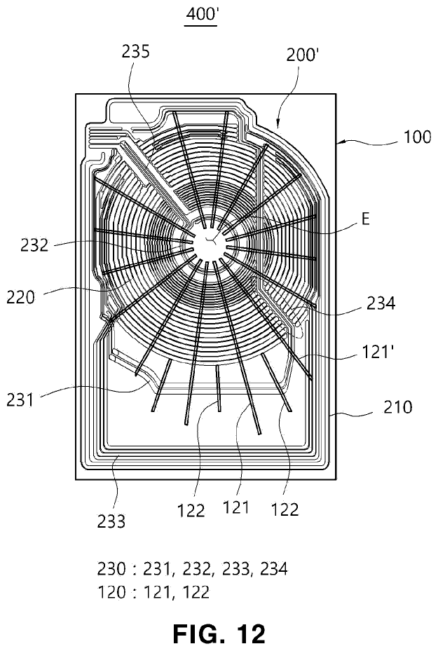

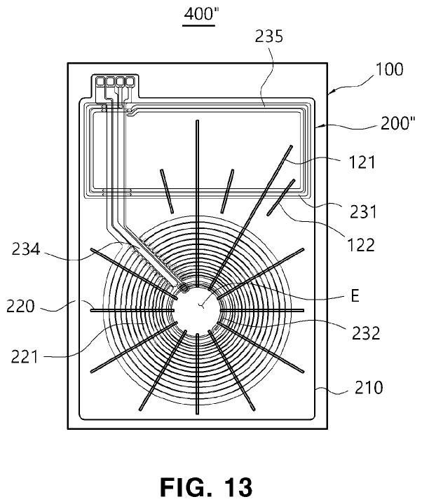

Meanwhile, with reference to FIGS. 12 and 13, as shown in FIGS. 8 and 9, antenna units 200′ and 200″ to which the heat-dissipating magnetic field shielding sheet 100 in which the eddy current reduction pattern part 120 has the first eddy current reduction pattern part 121 and the second eddy current reduction pattern part 122 is applied will be described.

In an embodiment of the present invention, the antenna unit 200′, 200″ may be a combo antenna unit including a first antenna 220 and a second antenna 230, as described above. Here, as shown in FIGS. 12 and 13, the first antenna 220 may include a radiation pattern 221 disposed on one side of a circuit board 210 and wound multiple times around a central portion E having a predetermined area. In addition, the second antenna 230 may include a first pattern 231, a second pattern 232, and a connection pattern 233, 234.

In this case, the first pattern 231, the second pattern 232, and the connection pattern 233, 234 may each refer to a portion of the entire second antenna 230. And, the first pattern 231, the second pattern 232, and the connection pattern 233, 234 may be formed to be physically connected to each other, or each may be formed independently.

In addition, the first pattern 231, the second pattern 232, and the connection pattern 233, 234 may all be formed with the same type of antenna, or may be formed by mixing different types of antennas. For example, the above-described first pattern 231, second pattern 232, and connection pattern 233, 234 may all be formed as NFC antennas, or may be formed by mixing an NFC antenna and an MST antenna.

Further, the second antenna 230 may be formed to include all of the first pattern 231, the second pattern 232, and the connection pattern 233, 234, or be formed to include only some of the above-described patterns.

Specifically, the first pattern 231 is a portion disposed outside the above-described radiation pattern 221 among the second antenna 230, and as shown in the drawing, may be arranged to be spaced apart from the radiation pattern 221 by a predetermined distance. In this case, the first pattern 231 may be placed in a space between the radiation pattern 221 and the outer edge of the shielding part 110 to improve wireless communication sensitivity in that space.

And, the first pattern 231 may be extended in a straight line form as shown in the drawing, may be extended in a circularly wound form similar to the radiation pattern 221, or may be formed to include both straight line and circular patterns. Meanwhile, the first pattern 231 shown in the drawing is only an example of the first pattern 231, and the first pattern 231 may have any shape as long as it is a part of the patterns of the second antenna 230 and is disposed outside the first antenna 220.

Next, the second pattern 232 is disposed inside the radiation pattern 221, that is, in a central portion E of the first antenna 220, and may be arranged in a wound form to form a circular loop similar to the first antenna 220.

In this case, the second pattern 232 may be disposed to increase sensitivity, for example, wireless communication sensitivity, by the second antenna in a region adjacent to the central portion E.

And, unlike the first pattern 231 and the second pattern 232 described above, the connection pattern 233, 234 may be arranged to overlap the radiation pattern 221 of the first antenna 220.

In an embodiment of the present invention, the connection pattern 233, 234 may refer to some regions extending in the radial direction of the radiation pattern 221 as shown in FIGS. 12 and 13 among various patterns of the second antenna 230 overlapping with the first antenna 220.

As a specific example, the connection pattern 233, 234 may include a first connection pattern 233 whose one end is connected to the above-described first pattern 231. In this case, the first connection pattern 233 may be disposed in a form that traverses the radiation pattern 221 to connect the first pattern 231 to a terminal or another pattern directly without bypassing the radiation pattern 221 on the circuit board 210 having a limited area.

As another example, the connection pattern 233, 234 may include a second connection pattern 234 having one end connected to the second pattern 232. In this case, the second connection pattern 234 may be arranged to traverse the radiation pattern 221 to connect the second pattern 232 disposed inside the radiation pattern 221 to a terminal or another pattern.

Meanwhile, referring to FIGS. 12 and 13, a third pattern 235 may be disposed in a region adjacent to the outer edge of the heat-dissipating magnetic field shielding unit 110. This third pattern 235 is a non-limiting example and may be disposed to transfer heat emitted from the antenna unit 200′, 200″ to a separate heat dissipation member (not shown) or a sensor member (not shown) for detecting temperature.

Looking at the specific positional relationship between the antenna unit 200′, 200″ and the eddy current reduction pattern part 120, as shown in FIGS. 12 and 13, the first eddy current reduction pattern part 121 may include linear patterns in which a plurality of linear patterns are radially disposed around the central portion E of the first antenna 220. Through this, the first eddy current reduction pattern part 121 can intersect both the first antenna 220 and the second antenna 230, as described above. Specifically, the first eddy current reduction pattern part 121 may intersect the radiation pattern 221 of the first antenna 220 and at the same time intersect at least one of the first pattern 231 and the second pattern 232 of the second antenna 230.

For example, the first eddy current reduction pattern part 121 may intersect both the first pattern 231 and the second pattern 232 formed on the outside and inside of the radiation pattern 221, and through this, even with the first eddy current reduction pattern part 121, it is possible to reduce the overall influence of eddy currents on respective parts 231 and 232 of the second antenna 230, which are positioned spaced apart from each other with the first antenna 220 interposed therebetween.

However, the application of the heat-dissipating magnetic field shielding sheet 100 according to an exemplary embodiment of the present invention is not limited to this, and depending on the design, the first eddy current reduction pattern part 120 may be arranged to intersect only one of the first pattern 231 and the second pattern 232.

Meanwhile, referring back to FIGS. 12 and 13, the first eddy current reduction pattern part 121 may be formed to be located to avoid a region where the first antenna 220 and the second antenna 230 overlap with each other.

For example, as shown in the drawing, the first eddy current reduction pattern part 121 may be disposed in a region other than in some regions in which the first connection pattern 233 connected to the first pattern 231 is disposed or in some regions in which the second connection pattern 234 connected to the second pattern 232 is disposed, among the radiation pattern 221.

In this regard, the inventor of the present invention conducted an experiment by comparing the case where the eddy current reduction pattern part 120 is arranged to overlap the connection pattern 233, 234 with the case where the eddy current reduction pattern part 120 is arranged to avoid the connection pattern 233, 234. As a result of the experiment, it was confirmed that the performance such as recognition distance of the NFC antenna corresponding to the second antenna was deteriorated when the eddy current reduction pattern part 120 was arranged to overlap the connection pattern 233, 234, whereas it was confirmed that the performance of the NFC antenna corresponding to the second antenna 230 was improved when it was placed to avoid the connection pattern 233, 234.

As such, the heat-dissipating magnetic field shielding sheet 100 according to an exemplary embodiment of the present invention may arrange the eddy current reduction pattern part 120 to avoid a region where the first antenna and the second antenna overlap with each other, thereby preventing antenna performance from being deteriorated due to the introduction of the eddy current reduction pattern part. Meanwhile, the second eddy current reduction pattern part 122 may be disposed between at least one pair of first eddy current reduction pattern parts 121 disposed adjacent to each other and be disposed to intersect with the pattern of the second antenna 230.

As a specific example, the second eddy current reduction pattern part 122 may be arranged to partially intersect only the first pattern 231 disposed outside the radiation pattern 221 as shown in FIGS. 12 and 13, thereby reducing the influence of eddy current on the antenna pattern disposed in a region between the first eddy current reduction pattern parts 121.

Further, in the drawing, the drawing shows that the second eddy current reduction pattern part 122 is formed only on the outside of the radiation pattern 221, but the second eddy current reduction pattern part 122 may be disposed between the first eddy current reduction pattern parts 121, and may be formed to intersect the second pattern 232 provided inside the radiation pattern 221.

In addition, the second eddy current reduction pattern part 122 may be disposed in a plurality of regions requiring eddy current reduction on the heat-dissipating magnetic field shielding unit 110, as shown in the drawing, and depending on the size of the space formed between the plurality of first eddy current reduction pattern parts 121, the second eddy current reduction pattern parts 122 may have different areas.

As such, the heat-dissipating magnetic field shielding sheet 100 according to an exemplary embodiment of the present invention includes a second eddy current reduction pattern part 122 having relatively small area loss, so that the number of first eddy current reduction pattern parts 121 that are formed in a relatively large area to reduce the magnetic permeability of the shielding part 110 can be minimized, while partially supplementing the effect of eddy current reduction to secure antenna performance.

Meanwhile, although not shown in FIGS. 11 to 13, the antenna unit 200, 200′, 200″ may further include a magnetic secure transmission (MST) antenna.

In addition, the antenna module 400, 400′, 400″ may be implemented as receiving modules in which the first antenna 220 or the first antenna 220 and the second antenna 230 act as receiving antennas for receiving predetermined signals, or may be implemented as transmission modules in which the first antenna 220 or the first antenna 220 and the second antenna 230 transmit signals to the outside.

Further, when the antenna module 400, 400′, 400″ is implemented as a signal receiving module, the antenna module 400, 400′, 400″ can be applied to portable terminal devices such as mobile phones and tablet PCs.

Although exemplary embodiments of the present invention have been described above, the idea of the present invention is not limited to the embodiments set forth herein. Those of ordinary skill in the art who understand the idea of the present invention may easily propose other embodiments through supplement, change, removal, addition, etc. of elements within the scope of the same idea, but the embodiments will be also within the idea scope of the present invention.

1. A heat-dissipating magnetic field shielding sheet, comprising:
a heat-dissipating magnetic field shielding unit, having:
a plurality of magnetic layers having at least one eddy current reduction pattern part formed thereon, and
a heat-dissipating adhesive member disposed between adjacent magnetic layers to improve heat transfer in the thickness direction of a magnetic field shielding unit.

2. The heat-dissipating magnetic field shielding sheet of claim 1, wherein the heat-dissipating magnetic field shielding sheet is a magnetic field shielding sheet arranged on one surface of an antenna, the antenna comprising: a hollow portion having a predetermined area in the center and a pattern part surrounding the hollow portion, wherein the eddy current reduction pattern part is provided at a position corresponding to a region in which the pattern part is disposed.

3. The heat-dissipating magnetic field shielding sheet of claim 1, wherein the magnetic layer is a soft magnetic alloy ribbon sheet comprising transition metals.

4. The heat-dissipating magnetic field shielding sheet of claim 1, wherein the eddy current reduction pattern part is a crack part in which a magnetic material constituting a magnetic layer in a predetermined region is divided into a plurality of pieces, or is a penetration part penetrating the predetermined region.

5. The heat-dissipating magnetic field shielding sheet of claim 1,
wherein the heat-dissipating magnetic field shielding sheet is attached to a first antenna and a second antenna, and
the eddy current reduction pattern part comprises: a first eddy current reduction pattern part formed to intersect both the first antenna and the second antenna, and a second eddy current reduction pattern part formed to intersect the second antenna.

6. The heat-dissipating magnetic field shielding sheet of claim 5,
wherein a plurality of first eddy current reduction pattern parts are arranged radially around a central portion of the first antenna, and
the second eddy current reduction pattern part is formed between at least one pair of the first eddy current reduction pattern parts disposed adjacent to each other to intersect the pattern of the second antenna.

7. The heat-dissipating magnetic field shielding sheet of claim 5,
wherein the first eddy current reduction pattern part and the second eddy current reduction pattern part are formed linearly with a predetermined width and length, and
the length of the second eddy current reduction pattern part is smaller than the length of the first eddy current reduction pattern part.

8. The heat-dissipating magnetic field shielding sheet of claim 5,
wherein the second antenna comprises a first pattern disposed outside the first antenna and a first connection pattern connected to the first pattern, and
the eddy current reduction pattern part is arranged so as not to overlap the first connection pattern.

9. The heat-dissipating magnetic field shielding sheet of claim 5,
wherein the second antenna comprises a second pattern disposed inside the first antenna and a second connection pattern connected to the second pattern, and
the eddy current reduction pattern part is arranged so as not to overlap the second connection pattern.

10. The heat-dissipating magnetic field shielding sheet of claim 1, wherein the heat-dissipating adhesive member is made of a heat-dissipating adhesive layer in which a heat dissipation filler in a binder matrix is dispersed, or is a heat dissipating double-sided tape having the heat-dissipating adhesive layer on both surfaces of a base material.

11. The heat-dissipating magnetic field shielding sheet of claim 10, wherein the heat dissipation filler comprises one or more of carbon-based components, metal components, and ceramic components.

12. The heat-dissipating magnetic field shielding sheet of claim 1, wherein the thickness of the magnetic layer is 15 to 35 μm, and the thickness of the heat-dissipating adhesive member is 3 to 50 μm.

13. The heat-dissipating magnetic field shielding sheet of claim 1, further comprising:
a protection part having a protective film disposed on one surface of the heat-dissipating magnetic field shielding unit; and
an attachment part disposed on the other surface of the heat-dissipating magnetic field shielding unit opposite to the one surface, and for fixing a magnetic field shielding sheet to an attachment target surface.

14. An antenna module, comprising:
an antenna unit having an antenna including a hollow portion having a predetermined area and a pattern part surrounding the hollow portion in the central portion; and
a heat-dissipating magnetic field shielding sheet according to claim 1 disposed on one surface of the antenna unit.

15. The antenna module of claim 14, wherein the antenna comprises one or more of an antenna for wireless power transmission (WPT), an antenna for magnetic secure transmission (MST), and an antenna for near field communication (NFC).

16. An electronic device comprising an antenna module according to claim 14.
